(19) United States
(12) Patent Application Publication
(10) Pub. No.: US 2009/0008670 A1
(43) Pub. Date: Jan. 8, 2009

(54) LED packaging structure with aluminum board and an LED lamp with said LED packaging structure

(75) Inventors: Chia-Chi Liu, Taipei Country (TW); Wen Kuei Tsai, Taipei County (TW)

Correspondence Address: BIRCH STEWART KOLASCH & BIRCH, PO BOX 747, FALLS CHURCH, VA, 22040-0747, US

(73) Assignee: Topco Technologies Corp.

(21) Appl. No.: 11/822,501

(22) Filed: Jul. 6, 2007

(51) Int. Cl. H01L 33/00

(52) U.S. Cl. 257/99; 257/E33.058

(57) ABSTRACT

An LED lamp is provided. The LED lamp has an aluminum board, a semiconductor substrate, at least a LED chip, a metal layer structure, and heat sink. The aluminum board has a cup structure thereon. The semiconductor substrate is assembled on a bottom surface of the cup structure. The LED chips are assembled on the semiconductor substrate. The metal layer structure is formed on a bottom surface of the aluminum board. The metal layer structure is composed of solderable materials. The heat sink is connected to the metal layer structure through solder joint.

### BACKGROUND OF THE INVENTION

(1) Field of the Invention

This invention relates to a light emitted diode (LED) packaging structure and an LED lamp, and more particularly relates to an LED packaging structure using aluminum board and an LED lamp with the LED packaging structure.

(2) Description of the Prior Art

Light emitted diode (LED) is a luminescence device transforming electric energy into optical energy with high efficiency and is also capable to be used as a small solid state illuminator. LED is mainly composed of a semiconductor p-n junction. A potential difference is applied to the p-n junction to generate electrons and holes flowing toward the junction surface. The electrons and holes are met and combined in the junction surface to generate illumination.

FIGS. 1 and 1A are cross-section views of a traditional LED lamp using copper board. As shown, the LED lamp 10 has a LED chip 14, a copper board 12, and a heat sink 20. The copper board 12 has a cup structure 12a thereon. The LED chip 14 is assembled on the bottom of the cup structure 12a. The cup structure 12a is filled with transparent material layer 16 so as to prevent the LED chip 14 from exposing to the environmental pollutant and moisture. The heat sink 20 is connected to a lower surface of the copper board 12 by using a solder material layer 30 as a solder joint for dissipating the heat generated by the LED chip 14.

However, the LED lamp 10 has the following drawbacks. First, the LED chip 14 is directly assembled on the copper board 12. Because the coefficients of thermal expansion of the chip material and copper are very much different (coefficient of thermal expansion of copper is greater than that of chip material), the expansion of copper board 12 due to the heat generated by the LED chip 14 may result a tensile force to crack the LED chip 14.

Secondly, copper is an ideal thermal conductive material but has a poor reflectivity. The cup structure 12a formed on the copper board 12 cannot reflect illumination generated by the LED chip 14 with high efficiency, and the illuminating efficiency of the LED lamp 10 is thus restricted. On the contrary, aluminum has a better reflectivity, but the heat sink cannot connect to an aluminum board by soldering for it is hard to have aluminum interact with solder material under normal soldering process. Other available methods for connecting the heat sink to the aluminum board, such as gluing or screw-fixing, always generate a high thermal resistance crossing the interface between the board and the heat sink. In addition, these connecting methods cannot provide a steady junction surface.

Attending with the development of high brightness LED lamp, multi-chip and large current designs have become a mainstream. However, multi-chip and large current design implies more heat being generated within the LED lamp. If the heat cannot be effectively dissipated, the circuit may be damaged to affect the normal operation of LED lamp.

Accordingly, in order to provide a high-brightness LED lamp with great illuminating efficiency, the demands of providing a board with great reflectivity and thermal dissipation event must be met.

### SUMMARY OF THE INVENTION

It is an object of the present invention to provide a LED lamp using aluminum board to enhance illuminating efficiency, and the aluminum board can be connected to the heat sink by soldering to enhance thermal dissipation event.

The LED lamp provided in the present invention has an aluminum board, a semiconductor substrate, at least a LED chip, a metal layer structure, and a heat sink. The semiconductor substrate is assembled on the aluminum board. The LED chip is assembled on the semiconductor substrate. The metal layer structure is formed on a bottom surface of the aluminum board. The metal layer structure is composed of solderable materials. The heat sink is connected to the metal layer structure through a solder joint.

In a preferred embodiment of the present invention, the aluminum board has a cup structure thereon. The semiconductor substrate is assembled on a bottom surface of the cup structure.

In a preferred embodiment of the present invention, a bottom surface of the aluminum board is a sanded coarse surface.

In a preferred embodiment of the present invention, a surface of the heat sink connecting to the metal layer structure is a sanded coarse surface.

### BRIEF DESCRIPTION OF THE DRAWINGS

The present invention will now be specified with reference to its preferred embodiment illustrated in the drawings, in which:

FIGS. 1 and 1A are cross-section views of a traditional LED lamp;

FIGS. 2 and 2A are cross-section views of a first preferred embodiment of the LED lamp in the present invention;

FIG. 3 is cross-section view of a preferred embodiment of the metal layer structure as shown in FIG. 2;

FIG. 4 is cross-section view of a second preferred embodiment of the LED lamp in the present invention;

FIG. 5 is cross-section view of a third preferred embodiment of the LED lamp in the present invention; and

FIG. 6 is cross-section view of a fourth preferred embodiment of the LED lamp in the present invention; and

FIG. 7 is cross-section view of a fifth preferred embodiment of the LED lamp in the present invention.

### DESCRIPTION OF THE PREFERRED EMBODIMENTS

FIGS. 2 and 2A are cross-section views showing a first preferred embodiment of the LED lamp 40 in the present invention. As shown, the LED lamp 40 has an aluminum board 42, a semiconductor substrate 43, at least a LED chip 44 (two LED chips 44 are shown in the present embodiment), a metal layer structure 48, and a heat sink 20. Wherein, the semiconductor substrate 43 is assembled on the aluminum board 42. Two LED chips 44 are assembled on the semiconductor substrate 43. The LED chips 44 may be connected to electrodes (not shown in this figure) formed on the aluminum board 42 by wiring or flip-chip connecting. The semiconductor substrate 43 and the LED chips 44 are covered with transparent material layer 46 to prevent the two LED chips 44 from exposing to the environmental pollutant and moisture.

The metal layer structure 48 is formed on a bottom surface of the aluminum board 42 by electroplating. It is noted that the metal layer structure 48 is composed of solderable materials, such as the material composed of Au, Sn, Ni, Ti, Ag, or Cu. In addition, there forms an LED packaging structure composed of the aluminum board 42, the semiconductor substrate 43, the LED chips 44, and the metal layer structure 48. The heat sink 20 is additional element connecting to the LED packaging structure to enhance thermal dissipation efficiency.

As shown, the heat sink 20 is connected to the bottom surface of the metal layer structure 48 by soldering. Therefore, a solder joint, such as a solder material layer 30 as shown, is formed between the heat sink 20 and the metal layer structure 48. To make sure that the heat sink 20 is steadily connected to the aluminum board 42, the thickness of the metal layer structure 48 is greater than 0.08 micron, and the thickness ranged between 0.2 to 10 microns would be a preferred embodiment.

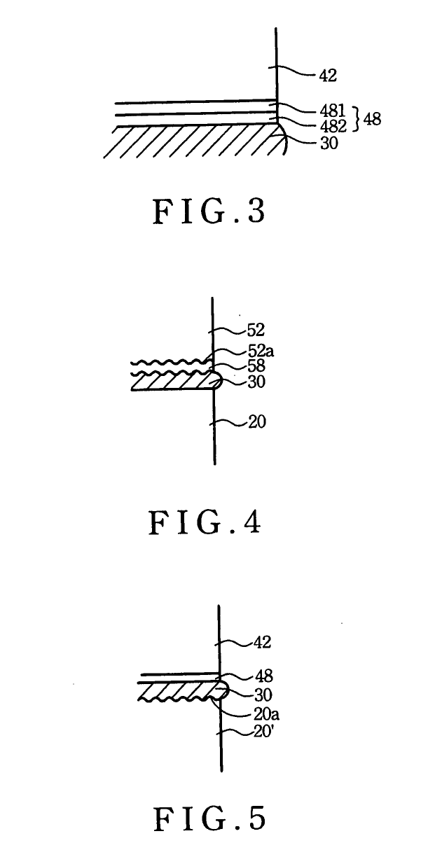

FIG. 3 shows a preferred embodiment of the metal layer structure 48 used in the embodiment of FIG. 2. As shown, the metal layer structure 48 is formed by electroplating a plurality of metal layers (twvo metal layers are shown in this figure) on the bottom surface of the aluminum board 42 in a serial for simplifying the manufacturing process. The metal layers may be composed of Ni, NiAg, NiCu, Au, or Sn. A Ni layer 481 and an Au layer 482 is used in the present embodiment.

FIG. 4 shows a cross-section view of a second preferred embodiment of the LED lamp in the present invention. In contrast with the embodiment of FIG. 2, the present embodiment features a coarse surface 52a formed on a bottom surface of the aluminum board 52 by sanding. The coarse surface 52a may increase the size of the interface between the aluminum board 52 and the metal layer structure 58 and also the interface between the metal layer structure 58 and the solder material layer 30. Therefore, the coarse surface 52a is helpful for increasing the stability of the joint between aluminum board 52 and the heat sink 20. Increasing of the size of the joint surface is helpful for reducing thermal resistance crossing the interface.

FIG. 5 shows a cross-section view of a third preferred embodiment of the LED lamp in the present invention. In contrast with the embodiment of FIG. 4, which features a coarse surface 52a formed on the bottom surface of the aluminum board 52, the present embodiment features a coarse surface 20a formed on the heat sink 20′. The coarse surface 20a is formed on a surface of the heat sink 20′ connecting to the metal layer structure 48. The existence of the coarse surface 20′ is helpful for increasing the stability of the joint between aluminum board 42 and the heat sink 20.

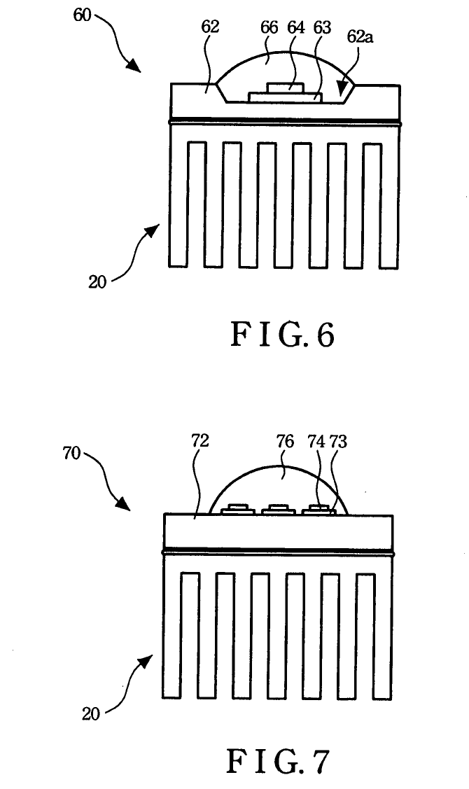

FIG. 6 shows a cross-section view of a fourth preferred embodiment of the LED lamp in the present invention. As shown, the aluminum board 42 has a cup structure 62a thereon with an opening facing upward. The semiconductor substrate 63 is assembled on a bottom surface of the cup structure 62a. At least an LED chip 64 (one LED chip is shown in this figure) is assembled on the semiconductor substrate 63. The cup structure 62a is filled with transparent material layer 66 to prevent the LED chip 64 from exposure to the environmental pollutant and moisture.

FIG. 7 shows a cross-section view of a fifth preferred embodiment of the LED lamp in the present invention. In contrast with the embodiment of FIG. 2 with only one semiconductor substrate 43 assembled on the aluminum board 42, the present embodiment has three semiconductor substrates 73 assembled on the aluminum board 72. Each semiconductor substrate 73 has at least an LED chip 74 (one LED chip is shown in this figure) thereon. The semiconductor substrate 73 and the LED chips 74 are covered with transparent material layer 76.

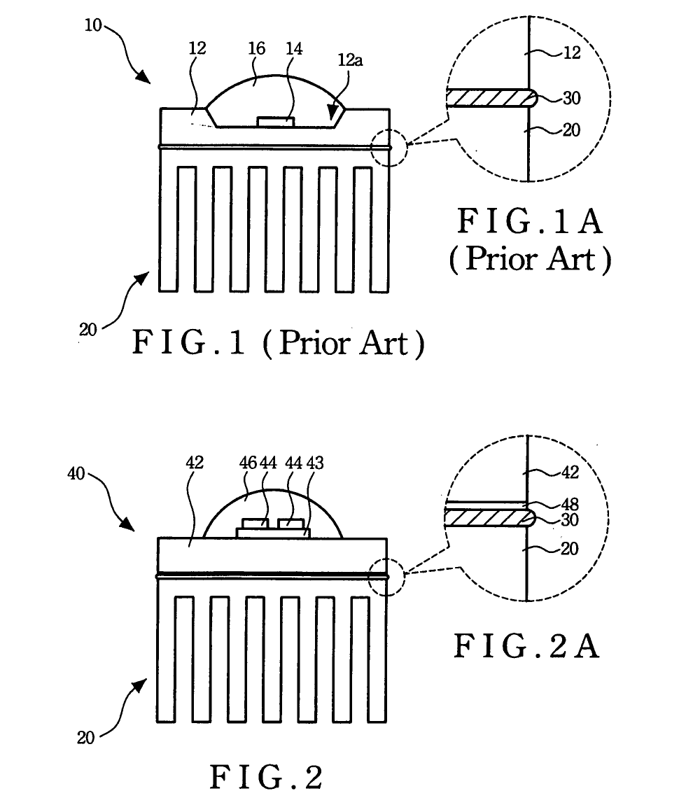

In contrast to the traditional LED lamp 10 shown in FIG. 1, which encounters the problem of poor reflectivity, the present invention uses aluminum board with better reflectivity instead to enhance the illuminating efficiency of the LED lamp. In addition, as to the problem that the aluminum board and the heat sink cannot be joined together by soldering, the present invention uses a metal layer structure electroplating on the bottom surface of the aluminum board to solve the problem. The metal layer structure can be connected to the heat sink by soldering. Thus, the heat sink can be steadily connected to the bottom surface of the aluminum board and the soldering joint is helpful for transmitting the heat generated by the LED chip to the heat sink.

As to the problem of joint strength, the second preferred embodiment of the present invention features a coarse surface formed by sanding to increase the interface size between the metal layer structure and the aluminum board. The coarse surface also increases the interface size between the metal layer structure and the heat sink to enhance the joint strength between the aluminum board and the heat sink.

While the embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

I claim:

1. An LED lamp comprising:
an aluminum board;
a semiconductor substrate, assembled on the aluminum board;
at least a LED chip, assembled on the semiconductor substrate;
a metal layer structure, formed on a bottom surface of the aluminum board, the metal layer structure being composed of solderable materials; and
a heat sink, connected to the metal layer structure through solder joint.

2. The LED lamp of claim 1, further comprising a transparent material layer, and the LED chip is covered with the transparent material layer.

3. The LED lamp of claim 1, wherein the metal layer structure is electroplated on a bottom surface of the aluminum board.

4. The LED lamp of claim 1, wherein the metal layer structure is composed of a plurality of metal layers formed on the bottom surface of the aluminum board in a serial.

5. The LED lamp of claim 1, wherein a thickness of the metal layer structure is greater than 0.08 micron.

6. The LED lamp of claim 1, wherein a bottom surface of the aluminum board is a sanded coarse surface.

7. The LED lamp of claim 1, wherein a surface of the heat sink connecting to the metal layer structure is a sanded coarse surface.

8. The LED lamp of claim 1, wherein the solderable material is composed of Au, Sn, Ni, Ti, Ag, or Cu.

9. The LED lamp of claim 1, wherein more than two LED chips are assembled on the semiconductor substrate.

10. The LED lamp of claim 1, wherein the aluminum board has a cup structure thereon, and the semiconductor substrate is assembled on a bottom surface of the cup structure.

11. An LED packaging structure comprising:
an aluminum board, having a cup structure thereon;
a semiconductor substrate, assembled on a bottom surface of the cup structure;
at least a LED chip, assembled on the semiconductor substrate; and
a metal layer structure, formed on a bottom surface of the aluminum board, the metal layer structure being composed of solderable materials.

12. The LED packaging structure of claim 11, wherein the metal layer structure is electroplated on the bottom surface of the aluminum board.

13. The LED packaging structure of claim 11, wherein the metal layer structure is composed of a plurality of metal layers formed on the bottom surface of the aluminum board in a serial.

14. The LED packaging structure of claim 11, wherein a thickness of the metal layer structure is greater than 0.08 micron.

15. The LED packaging structure of claim 11, wherein a bottom surface of the aluminum board is a sanded coarse surface.

16. The LED packaging structure of claim 11, wherein the solderable material is composed of Au, Sn, Ni, Ti, Ag, or Cu.

17. The LED packaging structure of claim 11, wherein more than two LED chips are assembled on the semiconductor substrate.

18. The LED packaging structure of claim 11, wherein the aluminum board has a cup structure thereon, and the semiconductor substrate is assembled on a bottom surface of the cup structure.
